(19) United States
(12) Patent Application Publication
(10) Pub. No.: US 2004/0195652 A1
(43) Pub. Date: Oct. 7, 2004

(54) Semiconductor device having inductor

(75) Inventor: Masakazu Okada, Hyogo (JP)

Correspondence Address: McDermott, Will & Emery, 600 13th Street, N.W., Washington, DC, 20005-3096, US

(73) Assignee: RENESAS TECHNOLOGY CORP.

(21) Appl. No.: 10/648,235

(22) Filed: Aug. 27, 2003

(30) Foreign Application Priority Data
Apr. 2, 2003 (JP) 2003-099209(P)

(51) Int. Cl. H01L 29/00

(52) U.S. Cl. 257/531

(57) ABSTRACT

A plurality of trenches are formed so as to penetrate a plurality of interlayer insulating films and silicon nitride films in a vertical direction. An interconnection layer is formed in each of the plurality of trenches such that the interconnection layers are stacked up. A plurality of stacked interconnection layers have the same width, and are provided so as to be stacked up one after another in the vertical direction. Therefore, all the parts of an inductor in the vertical direction contribute as the part for producing eddy current. Thus, a semiconductor device having the inductor which achieves lower resistance and a method of manufacturing the same can be obtained.

### BACKGROUND OF THE INVENTION

1. Field of the Invention

The present invention relates to a semiconductor device having an inductor on a semiconductor substrate, and a method of manufacturing the same.

2. Description of the Background Art

Conventionally, a semiconductor device has been known in which an interconnection layer of a spiral (helical) configuration is formed in each of a plurality of interlayer insulating films formed on the main surface of a semiconductor substrate, wherein a plurality of spiral interconnection layers serve as an inductor.

In the above conventional inductor, the plurality of spiral interconnection layers are provided spaced apart from each other by a predetermined distance in a direction perpendicular to the main surface of the semiconductor substrate. The plurality of interconnection layers are connected with each other by a plug embedded within a via hole extending in a vertical direction in the interlayer insulating film. A plurality of such plugs are provided vertically through the interconnection layers.

However, in each of the plurality of plugs, current flows only in the direction perpendicular to the main surface of the semiconductor substrate. That is, the plurality of plugs are the portion which does not contribute as an inductor.

Therefore, in the structure of the conventional inductor, it is difficult to reduce the resistance value of the inductor without increasing the area occupied by the inductor in a plane parallel to the main surface of the semiconductor substrate, or without increasing the number of the spiral interconnection layers stacked on each other.

### SUMMARY OF THE INVENTION

It is an object of the present invention to provide a semiconductor device which achieves lower resistance of an inductor, and a method of manufacturing the same.

A semiconductor device in accordance with the present invention is a semiconductor device having an inductor on a semiconductor substrate. The semiconductor device is provided with a unit having an interlayer insulating film formed above the semiconductor substrate, a spiral trench formed in the interlayer insulating film, and an interconnection layer embedded within the spiral trench.

The inductor is configured by a plurality of units stacked up in a direction substantially perpendicular to the main surface of the semiconductor substrate. Further, a plurality of interconnection layers included in the plurality of units are arranged so as to be stacked up one after another in a direction perpendicular to the main surface of the semiconductor substrate. The plurality of interconnection layers are substantially identical in width.

According to the above configuration, the inductor is configured by the plurality of stacked-up interconnection layers, thereby eliminating the portion which does not contribute as the inductor. As a result, the resistance of the inductor can be reduced.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic diagram of an inductor of a semiconductor device in accordance with a first embodiment when viewed from the top.

FIGS. 2 to 4 are cross sectional views of the semiconductor device with the inductor in accordance with the first embodiment.

FIGS. 5 to 10 are views for describing a method of manufacturing the semiconductor device with the inductor of the first embodiment.

FIG. 11 is a schematic diagram of an inductor of a semiconductor device in accordance with a second embodiment when viewed from the top.

FIGS. 12 to 14 are cross sectional views of the semiconductor device with the inductor in accordance with the second embodiment.

FIGS. 15 to 20 are views for describing a method of manufacturing the semiconductor device with the inductor of the second embodiment.

FIG. 21 is a schematic diagram of an inductor of a semiconductor device in another example when viewed from the top.

### DESCRIPTION OF THE PREFERRED EMBODIMENTS

In the following, inductors in accordance with the embodiments of the present invention will be described with reference to the drawings.

### First Embodiment

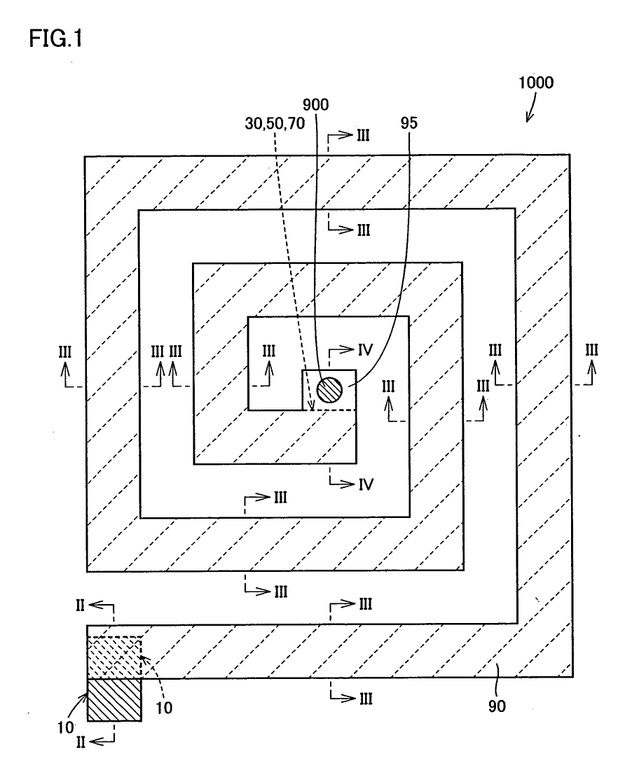

The structure of a semiconductor device having an inductor in accordance with a first embodiment and a method of manufacturing the same will be described with reference to FIGS. 1 to 10. First, the structure of the inductor will be described with reference to FIGS. 1 to 4.

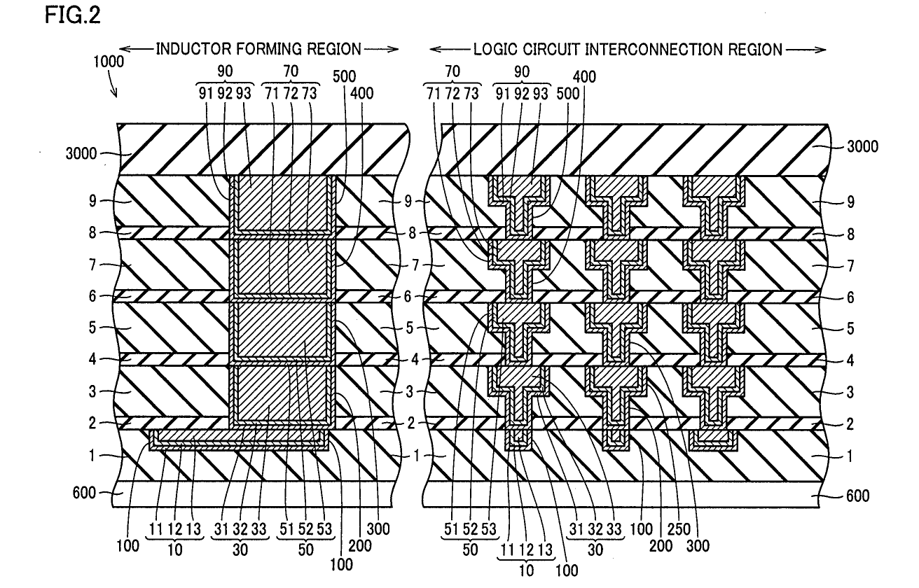

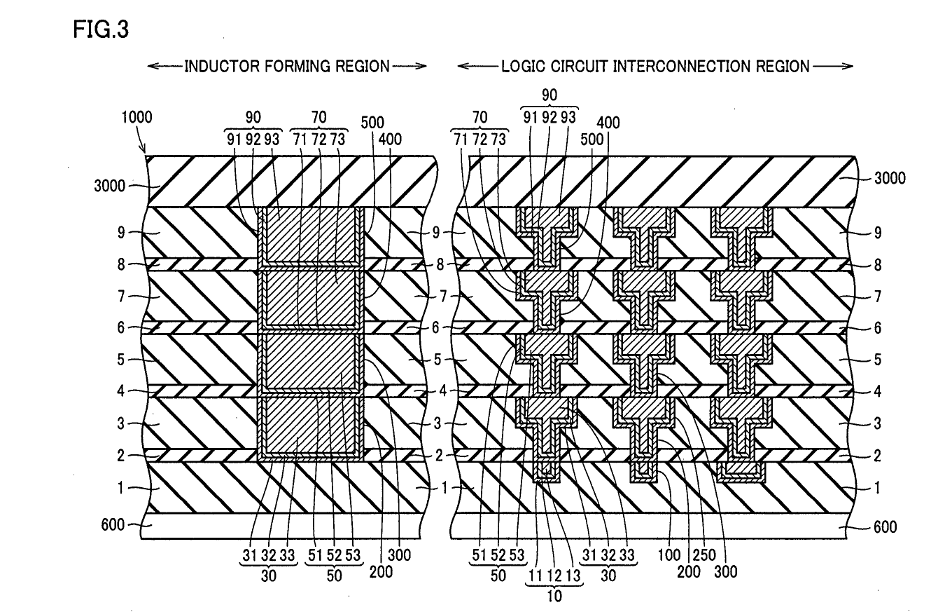

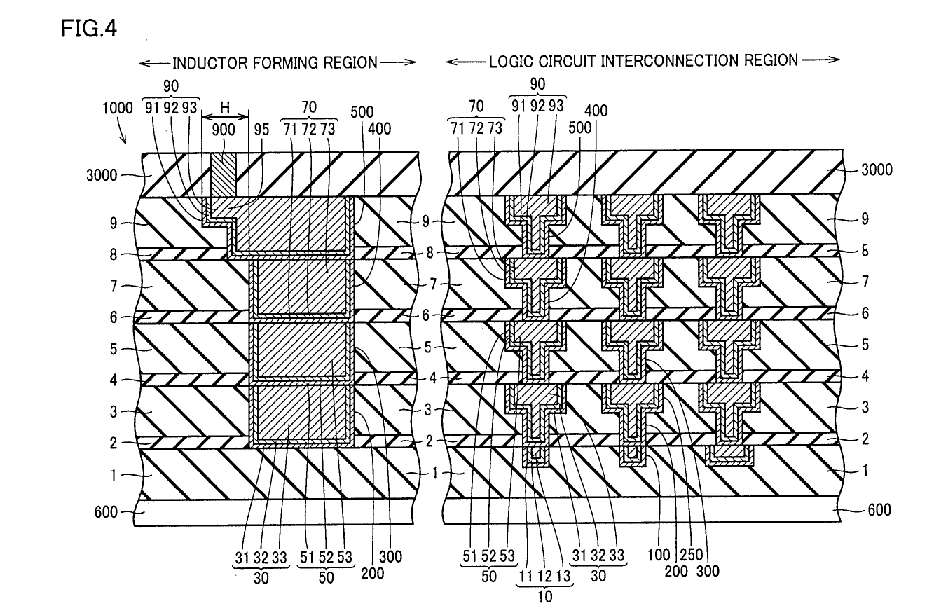

The inductor in the present embodiment has a spiral configuration as shown in FIG. 1 when viewed from a direction perpendicular to the main surface of a semiconductor substrate. In FIG. 1, the spiral structure is configured with a straight portion and a 90° angle bent portion. FIG. 2 is a cross sectional view taken along the line II-II shown in FIG. 1. FIG. 3 is a cross sectional view taken along the line III-III shown in FIG. 1. FIG. 4 is a cross sectional view taken along the line IV-IV shown in FIG. 1.

In addition, FIGS. 2, 3, and 4 show cross sectional structures of interconnection layers at a logic circuit interconnection region corresponding to respective layers of the inductor. In FIGS. 2, 3, and 4, whereas the logic circuit interconnection region is represented by only a predetermined cross sectional view, the inductor is represented by different cross sectional views of the inductor shown in FIG. 1.

As can be seen from FIG. 2, a trench 100 for an interconnection layer is formed in an interlayer oxide film 1 formed over a semiconductor substrate 600. A barrier metal film 11 is formed at the inner side of this interconnection layer trench 100. A seed Cu layer 12 is formed along the surface of barrier metal film 11. A Cu plating layer 13 is formed so as to fill a concave portion formed by seed Cu layer 12. Barrier metal film 11, seed Cu layer 12, and Cu plating layer 13 constitute an interconnection layer 10.

As can be seen from FIGS. 2 to 4, a silicon nitride film 2 is formed along the surface of interlayer oxide film 1. An interlayer oxide film 3 is formed over silicon nitride film 2. A trench 200 for an interconnection layer is formed so as to penetrate interlayer oxide film 3 and silicon nitride film 2.

A barrier metal film 31 is formed at the inner side of interconnection layer trench 200. A seed Cu layer 32 is formed along the surface of barrier metal film 31. A Cu plating layer 33 is formed so as to fill a concave portion formed by seed Cu layer 32. Barrier metal film 31, seed Cu layer 32, and Cu plating layer 33 constitute an interconnection layer 30.

Further, a silicon nitride film 4 is formed over interlayer oxide film 3. An interlayer oxide film 5 is formed over silicon nitride film 4. A trench 300 for an interconnection layer is formed so as to penetrate interlayer oxide film 5 and silicon nitride film 4.

A barrier metal film 51 is formed at the inner side of interconnection layer trench 300. A seed Cu layer 52 is formed along the surface of barrier metal film 51. A Cu plating layer 53 is formed so as to fill a concave portion formed by seed Cu layer 52. Barrier metal film 51, seed Cu layer 52, and Cu plating layer 53 constitute an interconnection layer 50.

Further, a silicon nitride film 6 is formed over interlayer oxide film 5. An interlayer oxide film 7 is formed over silicon nitride film 6. A trench 400 for an interconnection layer is formed so as to penetrate interlayer oxide film 7 and silicon nitride film 6.

A barrier metal film 71 is formed at the inner side of interconnection layer trench 400. A seed Cu layer 72 is formed along the surface of barrier metal film 71. A Cu plating layer 73 is formed so as to fill a concave portion formed by seed Cu layer 72. Barrier metal film 71, seed Cu layer 72, and Cu plating layer 73 constitute an interconnection layer 70.

Further, a silicon nitride film 8 is formed over interlayer oxide film 7. An interlayer oxide film 9 is formed over silicon nitride film 8. A trench 500 for an interconnection layer is formed so as to penetrate interlayer oxide film 9 and silicon nitride film 8.

A barrier metal film 91 is formed at the inner side of interconnection layer trench 500. A seed Cu layer 92 is formed along the surface of barrier metal film 91. A Cu plating layer 93 is formed so as to fill a concave portion formed by seed Cu layer 92. Barrier metal film 91, seed Cu layer 92, and Cu plating layer 93 constitute an interconnection layer 90. An interlayer insulating film (SiO₂) 3000 is formed over interlayer oxide film 9 so as to cover interconnection layer 90.

As can be seen from FIG. 2, interconnection layer 10 protrudes outwardly beyond interconnection layer 30 when seen from the direction perpendicular to the main surface of semiconductor substrate 600. In addition, as can be seen from FIGS. 2 to 4, interconnection layers 30, 50, 70, and 90 have the same width and penetrate in the vertical direction.

Further, as shown in FIG. 4, uppermost interconnection layer 90 has a protrusion 95 which protrudes outwardly beyond interconnection layers 30, 50, and 70 by a distance H. This protrusion 95 will be an upper drawing electrode of the inductor. A lower drawing electrode of the inductor is interconnection layer 10.

The semiconductor device as described above is provided with interlayer oxide films 3, 5, 7, and 9 formed over semiconductor substrate 600. In interlayer oxide films 3, 5, 7, and 9, spiral trenches 200, 300, 400, and 500 are formed, respectively. Interconnection layers 30, 50, 70, and 90 are embedded in spiral trenches 200, 300, 400, and 500, respectively.

The interlayer insulating film, the interconnection layer, and the spiral trench constitute a unit. An inductor 1000 is configured by a plurality of units stacked up in the direction substantially perpendicular to the main surface of semiconductor substrate 600.

Interconnection layers 30, 50, 70, and 90 included in the plurality of units have a substantially identical width, and are arranged so as to be stacked up one after another in the direction perpendicular to the main surface of semiconductor substrate 600.

According to the semiconductor device in the present embodiment as described above, all the parts constituting inductor 1000 is formed in a spiral structure. That is, inductor 1000 is formed as spiral interconnection layers 30, 50, 70, and 90 in all the plane cross sections parallel to the main surface of the semiconductor substrate, absent a via hole penetrating in the vertical direction as in the prior art. Therefore, eddy current can be produced at all regions in the vertical direction of the inductor.

Consequently, lower resistance of inductor 1000 can be achieved. In other words, in the semiconductor device described above, inductor 1000 is configured by the plurality of interconnection layers 30, 50, 70, and 90 which are stacked up, thereby eliminating a portion which does not contribute as the inductor. As a result, resistance of inductor 1000 can be reduced.

Further, widths of spiral trenches 200, 300, 400, and 500 are greater than film thicknesses of interlayer oxide films 3, 5, 7, and 9 of the unit to which interconnection layers 30, 50, 70, and 90 belong, respectively.

The above configuration can reduce a possibility of causing a failure in embedding interconnection layers 30, 50, 70, and 90 in spiral trenches 200, 300, 400, and 500, respectively.

Interconnection layer 90 included in the uppermost layer unit of the plurality of units located at a position farthest from semiconductor substrate 600 is provided with a drawing electrode portion which can draw current from inductor 1000. As shown in FIG. 4, the drawing electrode portion has protrusion 95 which protrudes beyond the outermost edges of interconnection layers 30, 50, and 70 included in the units below the uppermost layer unit, in a direction perpendicular to the main surface of interlayer oxide film 9. Interlayer insulating film 3000 is formed over the uppermost layer unit. Further, a contact plug 900 penetrating interlayer insulating film 3000 is formed from the upper side of protrusion 95, so as to connect with protrusion 95.

According to the above configuration, even if contact plug 900 penetrates protrusion 95 of interconnection layer 90 in the uppermost layer unit, interconnection layer 70 included in the unit below the uppermost layer unit is prevented from being exposed. Accordingly, interconnection layer 70 included in the unit below the uppermost layer unit is prevented from being oxidized. As a result, it is possible to prevent increase in resistance of inductor 1000 due to an error in a position for forming contact plug 900.

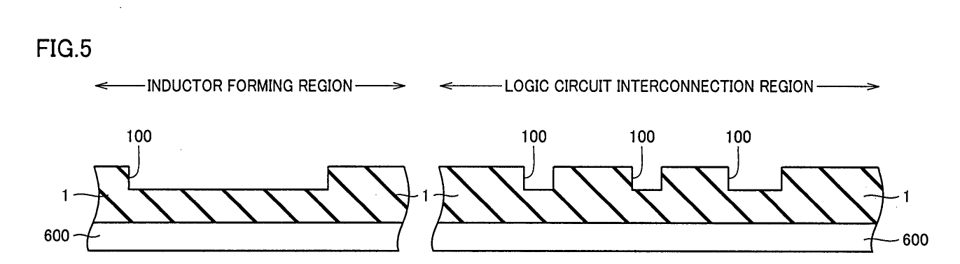

Next, a method of manufacturing a semiconductor device having an inductor will be described with reference to FIGS. 5 to 10.

First, interlayer oxide film (SiO₂) 1 is formed over semiconductor substrate 600. Then, a resist film is provided over interlayer oxide film 1. Using this resist film as a mask, interlayer oxide film 1 is etched, thereby forming interconnection layer trench 100 in interlayer oxide film 1, as shown in FIG. 5. At this time, interconnection layer trench 100 is formed at each of the inductor forming region and the logic circuit interconnection region.

Next, interconnection layer 10 is formed within interconnection layer trench 100. In the process of forming interconnection layer 10, barrier metal film 11 is first formed along the surface of interlayer oxide film 1. Then, seed Cu layer 12 is sputtered so as to follow the surface of barrier metal film 11.

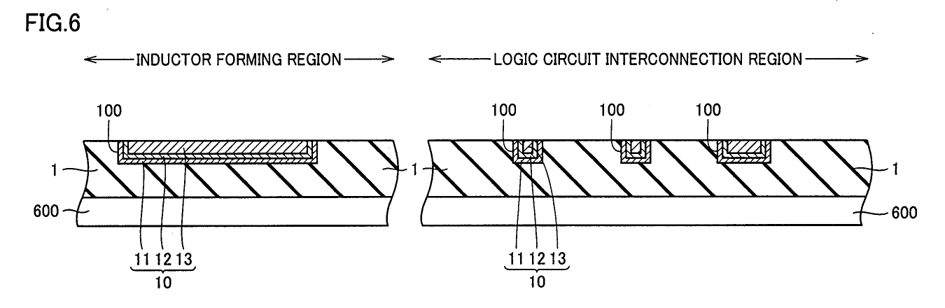

Thereafter, Cu plating layer 13 is formed over seed Cu layer 12. Then, barrier metal film 11, seed Cu layer 12, and Cu plating layer 13 are polished by CMP (Chemical Mechanical Polishing) until the surface of interlayer oxide film 1 is exposed. Thus, a structure as shown in FIG. 6 is obtained.

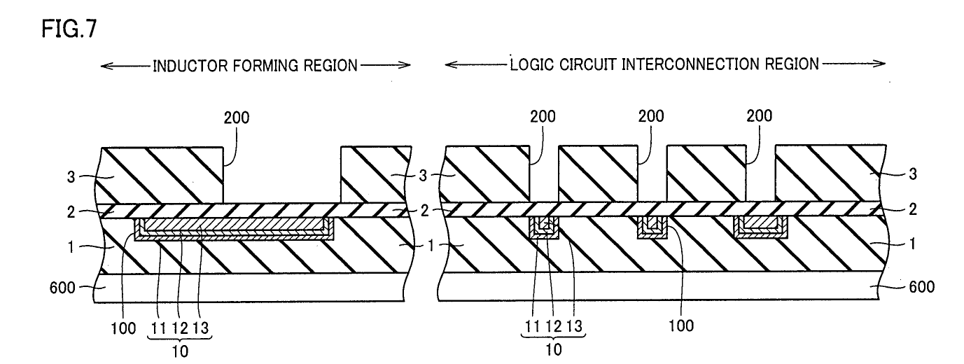

Next, silicon nitride film 2 is formed so as to cover the surfaces of interconnection layer 10 and interlayer oxide film 1. Interlayer oxide film 3 is formed over silicon nitride film 2. A resist film is formed over interlayer oxide film 3. Photolithography process is performed to transfer a predetermined pattern to the resist film, thereby forming the predetermined pattern onto the resist film. Using the predetermined pattern, interlayer oxide film 3 is anisotropically etched, thereby forming interconnection layer trench 200 in interlayer oxide film 3, as shown in FIG. 7.

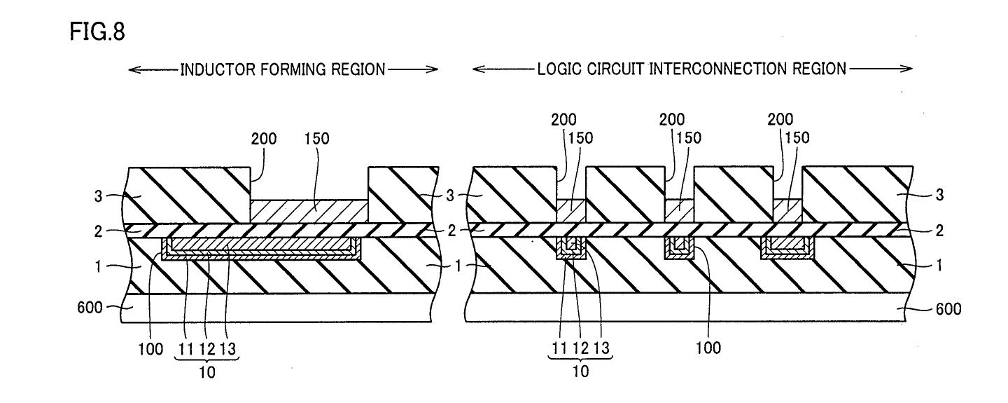

Then, a filler, which is an organic material, is applied so as to follow the surface of interconnection layer trench 200 and the surface of silicon nitride film 2. Thereafter, the filler is etched back to form a plug 150 made of an organic material at a position from the bottom of interconnection layer trench 200 to a predetermined height. Thus, a structure shown in FIG. 8 is obtained.

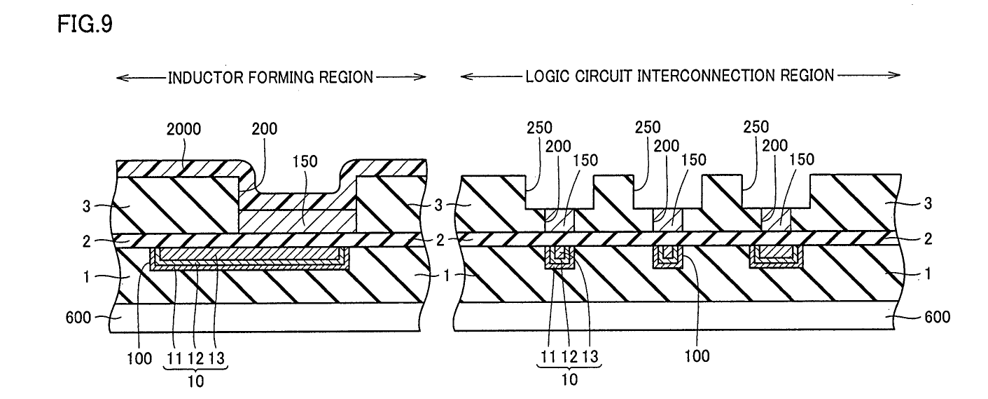

Next, a resist film 2000 shown in FIG. 9 is formed only over interlayer oxide film 3 and plug 150 at the inductor forming region in which inductor 1000 is being formed. That is, resist film 2000 is not formed over interlayer oxide film 3 at the logic circuit region. Etching is performed, using resist film 2000 as a mask. Here, as shown in FIG. 9, a trench 250 for an interconnection layer, which has a width greater than that of interconnection layer trench 200, is formed at the upper part of interconnection layer trench 200 at the logic circuit region.

Further, in the previously described etching process, plug 150 shown in FIG. 8 serves as a protection member to protect silicon nitride film 2 from being reduced. If plug 150 is not provided, silicon nitride film 2 would be exposed, thus silicon nitride film 2 would be etched. As a result, Cu plating layer 13 located below silicon nitride film 2 would be oxidized. Therefore, plug 150 prevents Cu plating layer 13 from oxidation. Thereafter, plug 150 and silicon nitride film 2 at the bottom of interconnection layer trench 200 are removed.

Next, barrier metal film 31 is formed so as to follow the surface of interlayer oxide film 3 in which spiral trench 200, interconnection layer trench 200, and interconnection layer trench 250 are formed. Then, seed Cu layer 32 is sputtered over barrier metal film 31, and Cu plating layer 33 is formed over seed Cu layer 32.

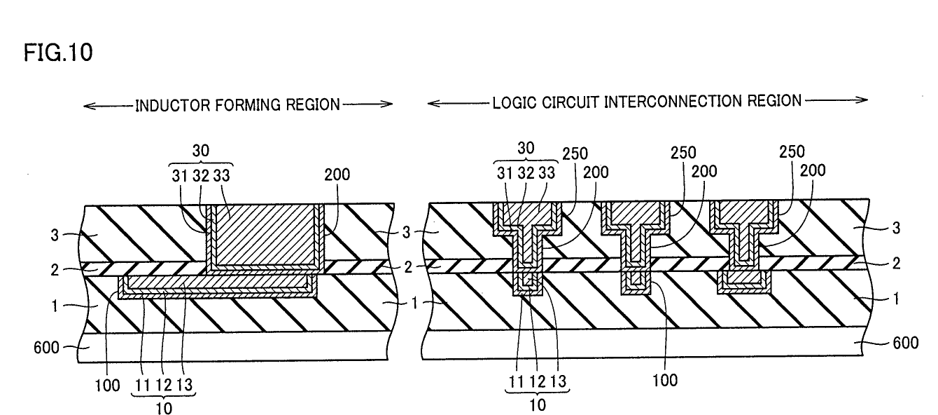

Thereafter, barrier metal film 31, seed Cu layer 32, and Cu plating layer 33 are polished by CMP until the upper surface of interlayer oxide film 3 is exposed, thus obtaining a structure as shown in FIG. 10. By repeating the previously described process of forming a unit including silicon nitride film 2, interlayer oxide film 3, and interconnection layer 30 in sequence, the inductor having the structure shown in FIGS. 2 to 4 can be manufactured.

The previously described semiconductor device is provided with the logic circuit region which is a region different from the region where inductor 1000 is formed, and in which a logic circuit is formed. The logic circuit region is provided with interconnection layers 10, 30, 50, 70, and 90 which constitute the logic circuit. The steps of forming spiral trenches 200, 300, 400, and 500 are performed together with parts of the steps of forming trenches 200, 300, 400, and 500 for the interconnection layers of the logic circuit in which interconnection layers 30, 50, 70, and 90 of the logic circuit are embedded. That is, the step of forming spiral trench 200 partially overlaps with the step of forming interconnection layer trench 200 in the logic circuit interconnection region.

The step of forming trench 200 for the interconnection layer of the logic circuit includes the step of forming a first trench 200 for the interconnection layer by performing the above-mentioned part of the step to interlayer oxide film 3. Further, the steps of forming trenches 200 and 250 for the interconnection layers of the logic circuit include the step of etching interlayer oxide film 3 in which the first trench 200 for the interconnection layer is formed after the step of forming the first trench 200 for the interconnection layer, to form a second trench 250 for the interconnection layer which has a width greater than that of the first trench 200 for the interconnection layer, over the first trench 200 for the interconnection layer.

Furthermore, as shown in FIG. 9, in the step of forming the second trench 250 for the interconnection layer, etching to form the second trench 250 for the interconnection layer is performed with spiral trench 200 at the inductor forming region covered with resist film 2000 serving as a mask.

According to the above manufacturing method, since spiral trench 200 at the inductor region is not etched when the second trench 250 for the interconnection layer is formed, the width of spiral trench 200 can be maintained.

### Second Embodiment

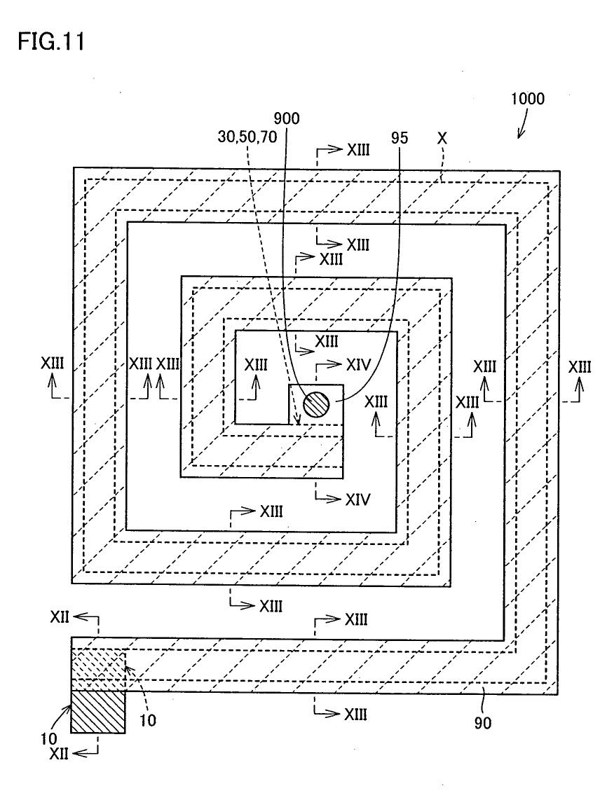

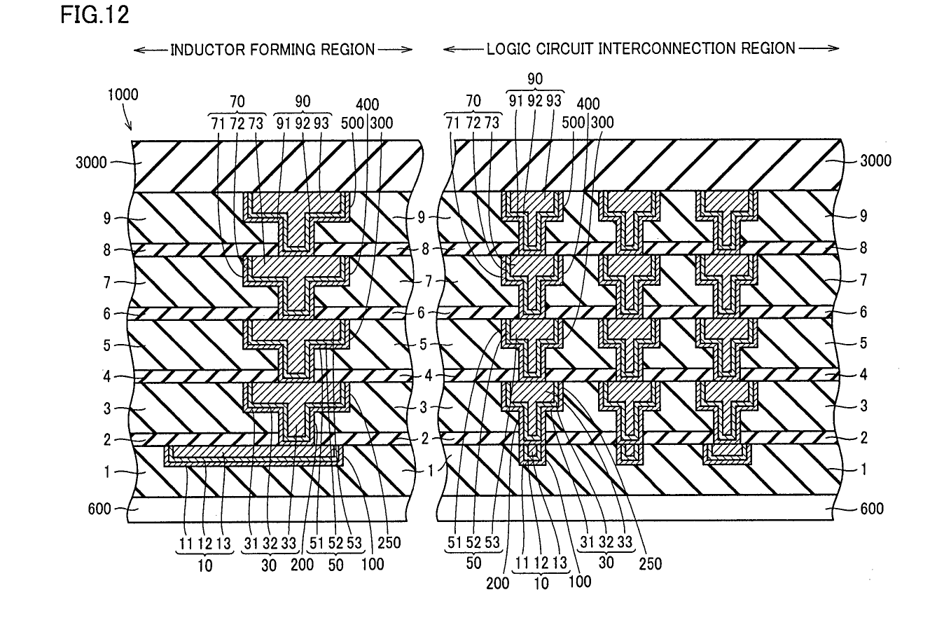

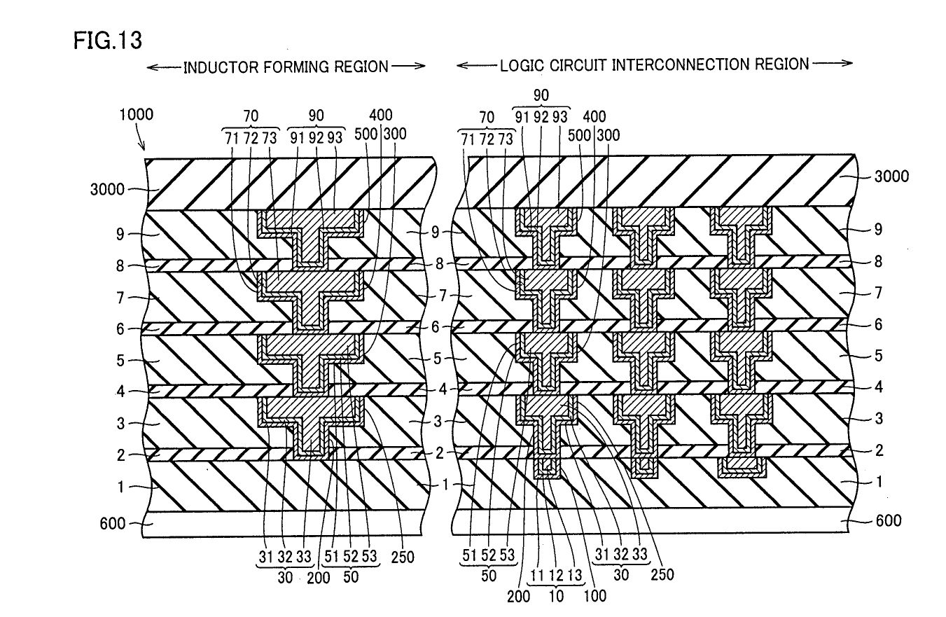

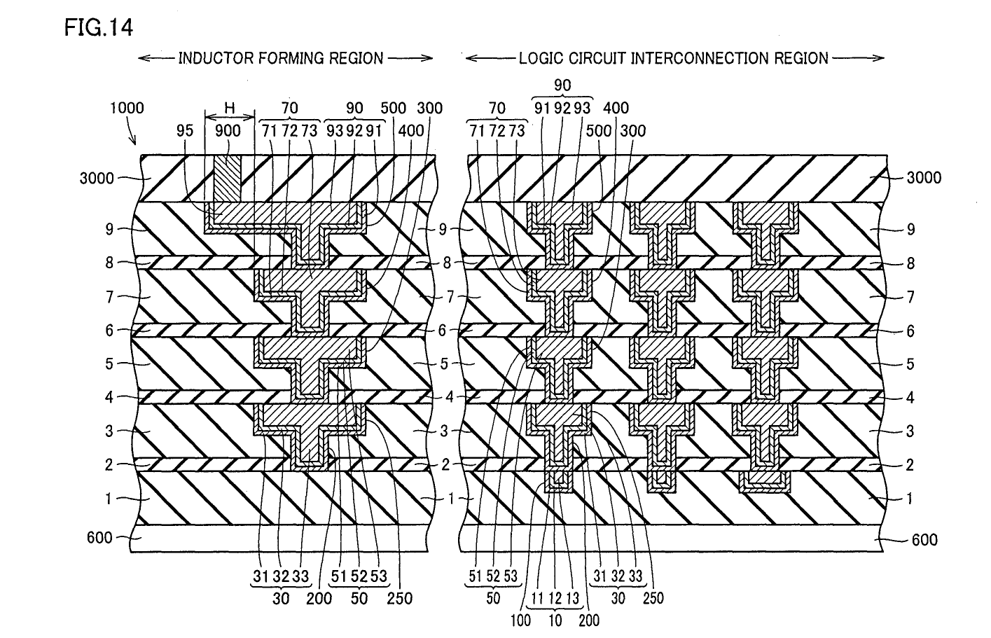

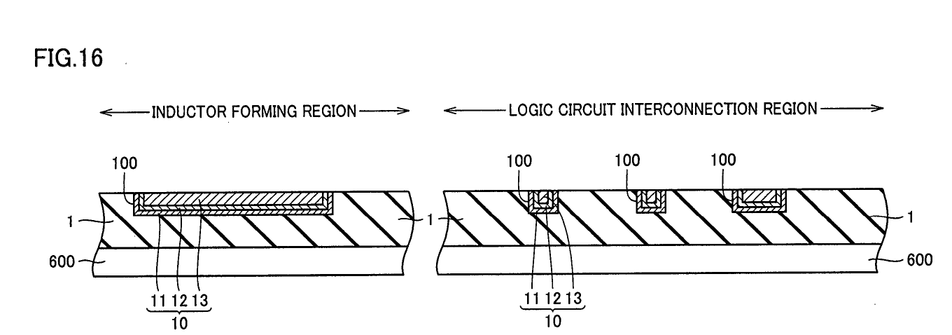

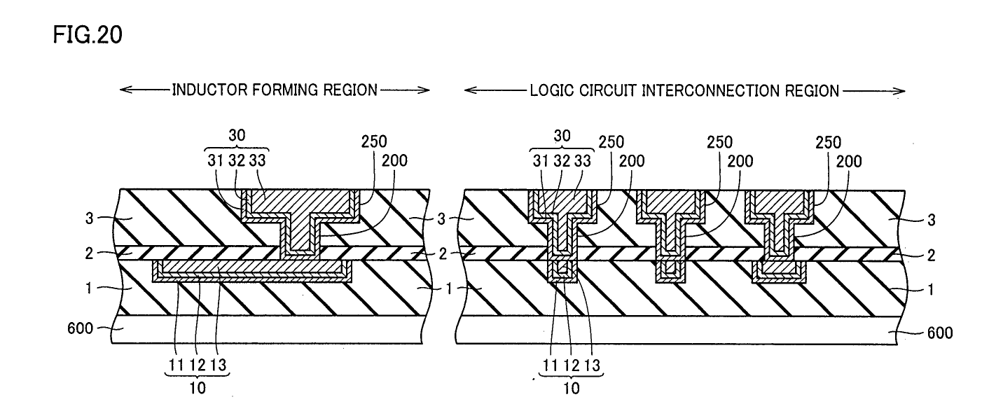

Next, the structure and a method of manufacturing a semiconductor device having an inductor in accordance with a second embodiment will be described with reference to FIGS. 11 to 20. First, the structure of the semiconductor device having the inductor will be described with reference to FIGS. 11 to 14. As shown in FIGS. 11 to 14, the structure of the semiconductor device having the inductor in accordance with the present embodiment is substantially identical to that of the semiconductor device having the inductor in accordance with the first embodiment described with reference to FIGS. 1 to 4. Each part of the semiconductor device of the present embodiment having the same reference character as that in the semiconductor device of the first embodiment is a part which performs the same function as that of the corresponding part in the semiconductor device of the first embodiment.

However, in the semiconductor device in accordance with the present embodiment, the cross section of trenches 200, 250 in which interconnection layer 30 is formed at the region of inductor 1000 exhibits lower trench 200 and upper trench 250 having different widths. The same applies to interconnection layers 50, 70, and 90. This is what differs from the structure of the semiconductor device in accordance with the first embodiment. The remaining elements in structure are identical to those of the first embodiment.

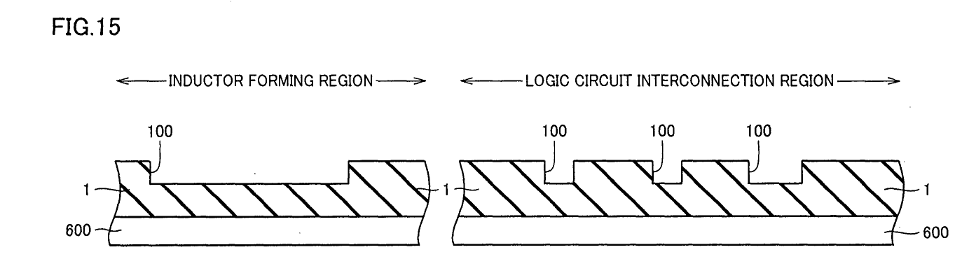

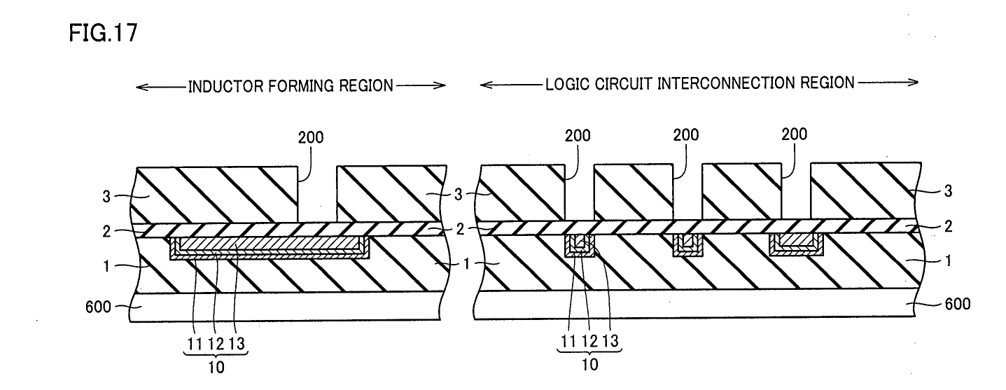

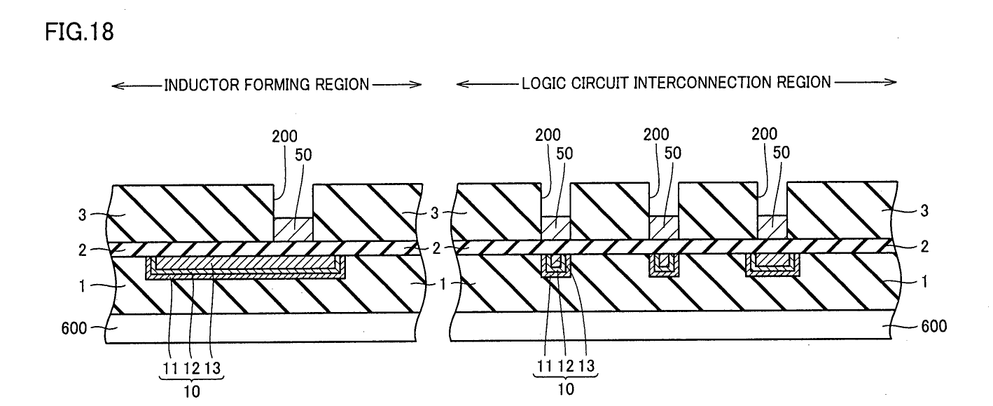

Also, in the method of manufacturing the semiconductor device shown in FIGS. 15 to 20, process steps substantially identical to those in the method of manufacturing the semiconductor device of the first embodiment described with reference to FIGS. 5 to 10 are performed. The difference between the manufacturing method in the first embodiment and that in the present embodiment is that, as shown in FIG. 17, the width of interconnection layer trench 200 at the region where inductor 1000 is being formed is smaller than that of interconnection layer trench 200 shown in FIG. 7. Further, an opening pattern is formed in a resist formed over spiral trench 200 such that the portion of interlayer oxide film 3 corresponding to the upper part of spiral trench 200 at the inductor forming region is also etched under the state shown in FIG. 18.

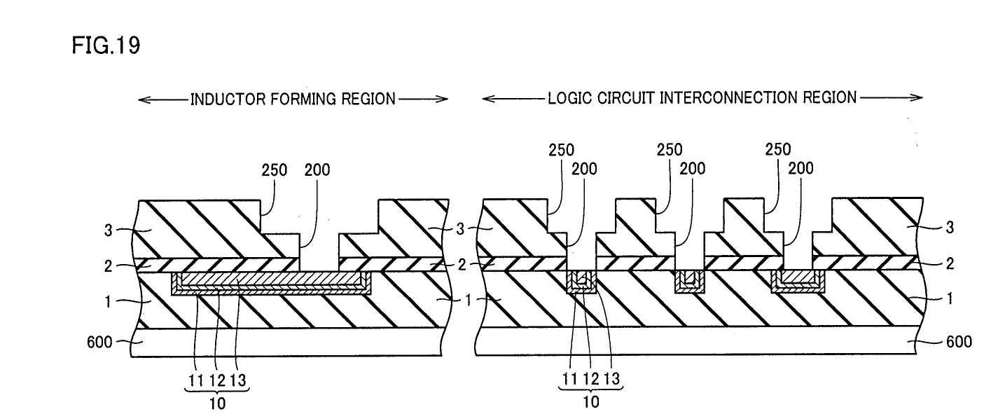

Therefore, as shown in FIG. 19, interconnection layer trench 250, which has a width greater than that of interconnection layer trench 200, is formed at the upper part of interconnection layer trench 200 at the region where inductor 1000 is being formed. The remaining manufacturing process steps performed in the present embodiment are identical to those in the first embodiment.

Also in the semiconductor device of the present embodiment as described above, effects similar to those obtained by the semiconductor device of the first embodiment can be achieved.

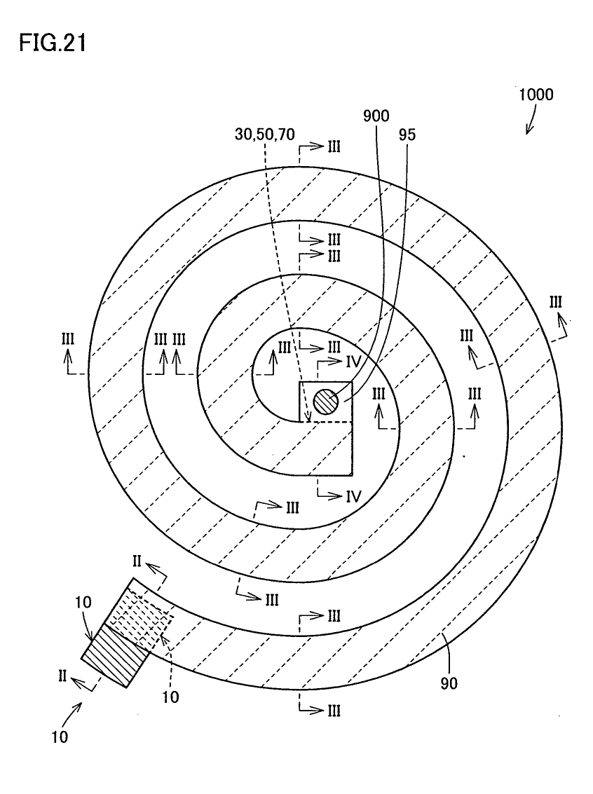

It is to be noted that the spiral interconnection layers shown in FIGS. 1 and 10 may have a curved spiral structure as shown in FIG. 21. With this structure, eddy current can be produced further smoothly, thereby achieving lower resistance of the inductor.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor device having an inductor on a semiconductor substrate, comprising a unit including:
an interlayer insulating film formed above said semiconductor substrate;
a spiral trench formed in said interlayer insulating film; and
an interconnection layer embedded within said spiral trench,
wherein said inductor is configured by a plurality of said units stacked up in a direction substantially perpendicular to a main surface of said semiconductor substrate, and
a plurality of said interconnection layers included in said plurality of units are arranged so as to be stacked up one- after another in a direction perpendicular to the main surface of said semiconductor substrate, and have a substantially identical width.

2. The semiconductor device according to claim 1, wherein a width of said spiral trench is greater than a film thickness of said interlayer insulating film in which said spiral trench is formed.

3. The semiconductor device according to claim 1, wherein
said interconnection layer included in an uppermost layer unit of said plurality of units located at a position farthest from said semiconductor substrate is provided with a drawing electrode portion which can draw current from said inductor;
said drawing electrode portion has a protrusion protruding beyond an outermost edge of said interconnection layer included in said unit below the uppermost layer unit, in a direction perpendicular to the main surface of said interlayer insulating film; and
a plug is formed from an upper side of said protrusion so as to connect with said protrusion.

4. A method of manufacturing the semiconductor device according to claim 1,
said semiconductor device being provided with a logic circuit region which is a region different from a region where said inductor is formed, and in which a logic circuit is formed, wherein said logic circuit region is provided with a logic circuit interconnection layer which constitutes said logic circuit;
the step of forming said spiral trench being performed together with a part of the step of forming a trench for the logic circuit interconnection layer in which said logic circuit interconnection layer is embedded; and
the step of forming the trench for said logic circuit interconnection layer including the steps of
forming a first trench portion by performing said part of the step to said interlayer insulating film, and
etching the interlayer insulating film in which the first trench portion is formed after the step of forming the first trench portion, to form a second trench portion which has a width greater than that of the first trench portion, over the first trench portion,
wherein, in the step of forming the second trench portion, etching to form said second trench portion is performed with said spiral trench covered with a mask.
